(19) United States
(12) Patent Application Publication
(10) Pub. No.: US 2013/0057254 A1
(43) Pub. Date: Mar. 7, 2013

(54) CURRENT MEASUREMENT CIRCUIT FOR INDUCTOR

(71) Applicant: YA-JUN PAN, Shenzhen City (CN)

(72) Inventor: YA-JUN PAN, Shenzhen City (CN)

(73) Assignees: HON HAI PRECISION INDUSTRY CO., LTD., Tu-Cheng (TW); HONG FU JIN PRECISION INDUSTRY (ShenZhen) CO. LTD., Shenzhen City (CN)

(21) Appl. No.: 13/444,808

(22) Filed: Apr. 11, 2012

(30) Foreign Application Priority Data
Sep. 1, 2011 (CN) 201110256700.3

(51) Int. Cl. G01R 19/32

(52) U.S. Cl. 324/105

(57) ABSTRACT

A current measurement circuit to measure current flowing through an inductor includes two metal oxide semiconductor field effect transistors, a resistor, a negative temperature coefficient thermistor, two capacitors, and a pulse width modulator.

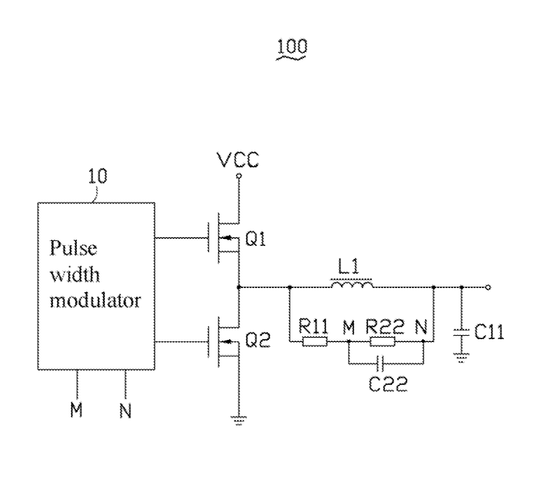

### BACKGROUND

1. Technical Field

The present disclosure relates to a circuit for measuring current through inductors.

2. Description of Related Art

In a power circuit, a pulse width modulator measures voltage on an inductor to obtain current flowing through the inductor. In other words, the voltage of the inductor is be divided by an inductance of the inductor to obtain the current flowing through the inductor. However, the inductance of the inductor varies when the temperature of the inductor varies. As a result, the current flowing through the inductor obtained by the operator is not accurate.

### BRIEF DESCRIPTION OF THE DRAWING

Many aspects of the embodiments can be better understood with reference to the drawings. The components in the drawings are not necessarily drawn to scale, the emphasis instead being placed upon clearly illustrating the principles of the present embodiments. Moreover, in the drawings, like reference numerals designate corresponding parts throughout the several views.

The FIGURE is a circuit diagram of an exemplary embodiment of a current measurement circuit.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

The FIGURE, is a current measurement circuit 100 for measuring the current flowing through an inductor L1. An exemplary embodiment of the current measurement circuit 100 includes a pulse width modulator 10, a first metal oxide semiconductor field effect transistor (MOSFET) Q1, a second MOSFET Q2, a first capacitor C11, a second capacitor C22, a resistor R11, and a negative temperature coefficient (NTC) thermistor R22.

The pulse width modulator 10 generates two control signals and respectively outputs the control signals to gates of the first MOSFET Q1 and the second MOSFET Q2. Frequency of each control signal is f. A drain of the first MOSFET Q1 is connected to a power supply VCC. A source of the second MOSFET Q2 is grounded. A source of the first MOSFET Q1 is connected to a drain of the second MOSFET Q2. The source of the first MOSFET Q1 is further grounded through the inductor L1 and the first capacitor C11 connected in series. A first terminal of the resistor R11 is connected to the source of the first MOSFET Q1. A second terminal of the resistor R11 is connected to a first terminal M of the thermistor R22. A second terminal N of the thermistor R22 is connected to a node between the inductor L1 and the first capacitor C11. The capacitor C22 is connected to the thermistor R22 in parallel. The first and second terminals M and N of the thermistor R22 are connected to the pulse width modulator 10. The pulse width modulator 10 measures voltage between the first and second terminals M and N of the thermistor R22. In the embodiment, the thermistor R22 is located adjacent to the inductor L1.

According to characters of the inductor, an inductive reactance of the inductor L1 can be obtained through a formula as followed:

IR=j*2*π*f*L (1), wherein IR stands for the inductive reactance of the inductor L1, L stands for an inductance of the inductor L1, j stands for an imaginary number unit, π stands for a mathematical constant, f stands for the frequency of the control signal. In addition, according to characters of the capacitors, a capacitive reactance of the capacitor can be obtained through a formula as followed:

CR=1/(j*2*π*f*C) (2), wherein CR stands for the capacitive reactance of the capacitor C22, C stands for a capacitance of the capacitor C22.

In this embodiment, the voltage of the inductor L1 is U_{L}, the current flowing through the inductor L1 is I_{L}, a formula as followed can be obtained: U_{L}=I_{L}*(j*2*π*f*L+DCR) (3), wherein DCR stands for an impedance of the inductor L1. In addition, U_{C} stands for the voltage of the capacitor C22, a formula as followed can be obtained:

$${U}_{C} = \frac{\frac{R 2 \text{/} ( S * C )}{R 2 + 1 \text{/} ( SC )}}{[ R 1 + \frac{R 2 \text{/} ( S * C )}{R 2 + 1 \text{/} ( S * C )} ]} * {U}_{L} = \frac{( 1 + \frac{S * L}{DCR} )}{( 1 + \frac{R 1 * R 2 * S * C}{R 1 + R 2} )} K * DCR * {I}_{L} , \qquad ( 4 )$$

wherein S=j

$$* 2 * π * f , K = \frac{R 2}{R 1 + R 2} ,$$

R1 stands for a resistance of the resistor R11, R2 stands for a resistance of the thermistor R22.

In addition, in the embodiment, the inductance L of the inductor L1, the impedance DCR of the inductor L1, the resistance R1 of the resistor R11, the resistance R2 of the thermistor R22, the capacitance C of the capacitor C22 of the current measurement circuit 100 are designed to fulfill a formula as followed:

$$\frac{L}{DCR} = \frac{R 1 * R 2 * C}{R 1 + R 2} . \qquad ( 5 )$$

As a result, when the formula (5) is applied with the formula (4), a formula as followed can be obtained: U_{C}=K*DCR*I_{L} (6). Thereby, the current I_{L} flowing through the inductor L1 can be obtained as followed:

$${I}_{L} = \frac{{U}_{C}}{K * DCR} . \qquad ( 7 )$$

When the current measurement circuit 100 operates, the pulse width modulator 10 detects the voltage UC of the thermistor R22. As a result, the current I_{L} flowing through the inductor L1 can be obtained according to the formula (7).

Actually, when the inductor L1 operates, the temperature of the inductor L1 increases, such that the impedance DCR of the inductor L1 increases. However, if the current IL flowing through the inductor L1 is obtained according to the formula (7), the value of the impedance DCR is invariable. In other words, the value of the impedance DCR in the formula (7) is less than the actual value of the impedance DCR of the inductor L1. In addition, when the temperature of the inductor L1 increases, the resistance R2 of the thermistor R22 decreases. According to the formula

$$K = \frac{R 2}{R 1 + R 2} ,$$

when the resistance R2 of the thermistor R22 decreases, the value of K also decreases. However, if the current IL flowing through the inductor L1 is obtained according to the formula (7), the value of K cannot be changed. But the value of K in the formula (7) is greater than the actual value of K. As a result, a difference between the current I_{L} flowing through the inductor L1 obtained according to the formula (7) and the actual I_{L} flowing through the inductor L1 decreases.

To describe a working principle of the current measurement circuit 100, the following example is given: the inductance L of the inductor L1 is equal to 0.29 microhenries (μH). The capacitance C of the capacitor C22 is equal to 0.1 microfarads (μF). The impedance DCR of the inductor L1 is equal to 0.29 milliohms when the temperature is 25 degrees Celsius. The impedance DCR of the inductor L1 is equal to 0.319 milliohms when the temperature is 50 degrees Celsius. The resistance R1 of the resistor R11 is equal to 1.15 kilohms The resistance R2 of the thermistor R22 is equal to 10 kilohms when the temperature is 25 degrees Celsius. The resistance R2 of the thermistor R22 is equal to 4.16 kilohms when the temperature is 50 degrees Celsius. As a result, when the temperature of the inductor L1 is 25 degrees Celsius, K*DCR=10*0.29/(10+1.15)=0.26. When the temperature of the inductor L1 is 50 degrees Celsius, K*DCR=4.16*0.319/(4.16+1.15)=0.248. However, if the resistor R22 is not a thermistor, the resistance of the resistor R22 is invariable when the temperature of the inductor L1 varies. At this condition, when the temperature of the inductor L1 is 50 degrees Celsius, K*DCR=10*0.319/(10+1.15)=0.286. Obviously, the difference between 0.26 and 0.248 is less than the difference between 0.26 and 0.286. As a result, because of the thermistor R22, the current measurement circuit 100 can reduce the error of the current flowing through the inductor L1 when the inductor L1 is at different temperatures.

The foregoing description of the exemplary embodiments of the disclosure has been presented only for the purposes of illustration and description and is not intended to be exhaustive or to limit the disclosure to the precise forms disclosed. Many modifications and variations are possible. The embodiments were chosen and described in order to explain the principles of the disclosure and their practical application so as to enable others of ordinary skill in the art to utilize the disclosure and various embodiments and with such modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than by the foregoing description and the exemplary embodiments described therein.

What is claimed is:

1. A current measurement circuit to measure current flowing through an inductor, comprising:
a pulse width modulator generating first and second control signals with the same frequency;
a first metal oxide semiconductor field effect transistor (MOSFET) comprising a gate connected to the pulse width modulator to receive the first control signal, a drain connected to a power supply, and a source;
a second MOSFET comprising a gate connected to the pulse width modulator to receive the second control signal, a drain connected to the source of the first MOSFET, and a source grounded;
a resistor comprising a first terminal connected to the source of the first MOSFET, and a second terminal;
a negative temperature coefficient thermistor comprising a first terminal connected to the second terminal of the resistor, and a second terminal;
an inductor comprising a first terminal connected to the source of the first MOSFET, and a second terminal connected to the second terminal of the negative temperature coefficient thermistor;
a first capacitor comprising a first terminal connected to the second terminal of the inductor, and a second terminal grounded; and
a second capacitor connected to the negative temperature coefficient thermistor in parallel;
wherein the negative temperature coefficient thermistor is located adjacent to the inductor.

2. The current measurement circuit of claim 1, wherein an inductance of the inductor is L, an impedance of the inductor is DCR, a capacitance of the second capacitor is C, a resistance of the resistor is R1, a resistance of the thermistor is R2, which satisfy the formula of
$$\frac{L}{DCR} = \frac{R 1 * R 2 * C}{R 1 + R 2} .$$

3. The current measurement circuit of claim 2, wherein the pulse width modulator measures voltage Uc of the thermistor, and the current I_{L} flowing through the inductor is obtained through a formula of
$${I}_{L} = \frac{{U}_{C}}{\frac{R 2}{R 1 + R 2} * DCR} .$$

4. The current measurement circuit of claim 2, wherein a resistance of the thermistor is 10 kilohms when the temperature is 25 degrees Celsius, and the resistance of the thermistor is equal to 4.16 kilohms when the temperature is 50 degrees Celsius; the impedance of the inductor is equal to 0.29 milliohms when the temperature is 25 degrees Celsius, and the impedance of the inductor is equal to 0.319 milliohms when the temperature is 50 degrees Celsius; the inductance of the inductor is equal to 0.29 microhenries, the capacitance of the second capacitor is equal to 0.1 microfarads, the resistance of the resistor is equal to 1.15 kilohms.
